(19) United States
(12) Patent Application Publication
(10) Pub. No.: US 2013/0258601 A1
(43) Pub. Date: Oct. 3, 2013

(54) HEAT DISSIPATION APPARATUS FOR ELECTRONIC DEVICE

(71) Applicant: Ji-Yun QIN, Shenzhen (CN)

(72) Inventor: Ji-Yun QIN, Shenzhen (CN)

(73) Assignees: Foxconn Technology Co., Ltd., Tu-Cheng (TW); CHAMP TECH OPTICAL (FOSHAN) CORPORATION, Foshan (CN)

(21) Appl. No.: 13/474,726

(22) Filed: May 18, 2012

(30) Foreign Application Priority Data
Mar. 28, 2012 (CN) 201210085107.1

(51) Int. Cl. H05K 7/20

(52) U.S. Cl. 361/714

(57) ABSTRACT

A heat dissipation apparatus adapted for cooling an electronic component received in a metal housing includes a heat sink thermally attached to the electronic component and plural of resilient tabs arranged between the heat sink and the metal housing. The resilient tabs are elastically deformed by the metal housing and thermally contact an inner face of the metal housing.

### BACKGROUND

1. Technical Field

The disclosure relates to heat dissipation, and particularly to a heat dissipation apparatus for use in an electronic device.

2. Description of Related Art

Nowadays, with the development of electronic technology, an electronic device such as a computer or a server is devised to be much thinner and smaller than before, yet hold many more electronic modules. However, the electronic modules generate a large amount of heat during operation. The interior space of the electronic device is very limited, and the electronic modules occupy much of that space, which results in heat generated by the electronic modules accumulating rather than being dissipated in timely manner.

What is needed, therefore, is a heat dissipation apparatus for an electronic device which can overcome the limitation described.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, assembled view of an electronic device in accordance with a first embodiment of the disclosure.

FIG. 2 is an isometric, exploded view of the electronic device of FIG. 1.

FIG. 3 is a partial, cross-sectional view of the electronic device of FIG. 1.

FIG. 4 is an isometric, exploded view of a heat dissipation apparatus of the electronic device of FIG. 1.

FIG. 5 is an inverted view of the heat dissipation apparatus of FIG. 4.

FIG. 6 is an isometric, assembled view of an electronic device in accordance with a second embodiment of the disclosure.

### DETAILED DESCRIPTION

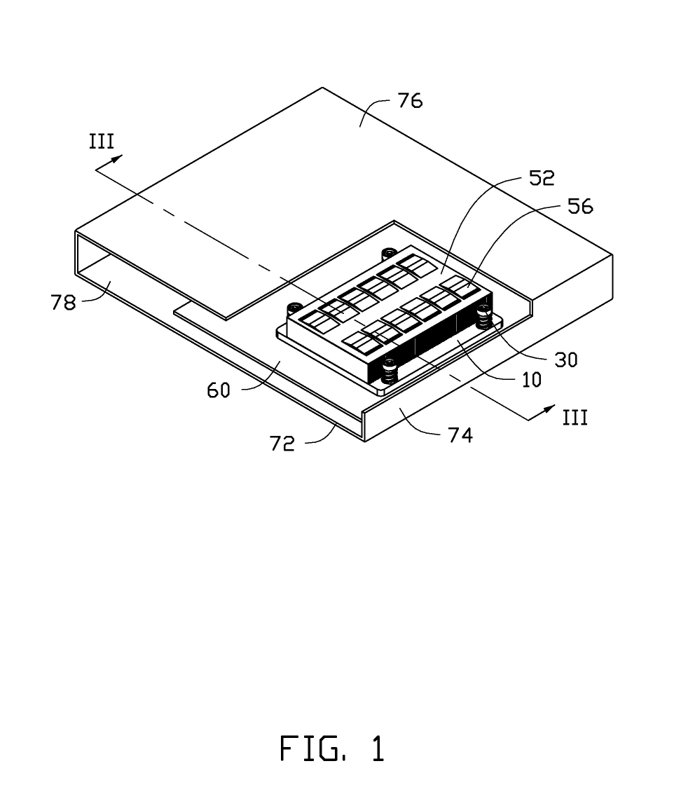

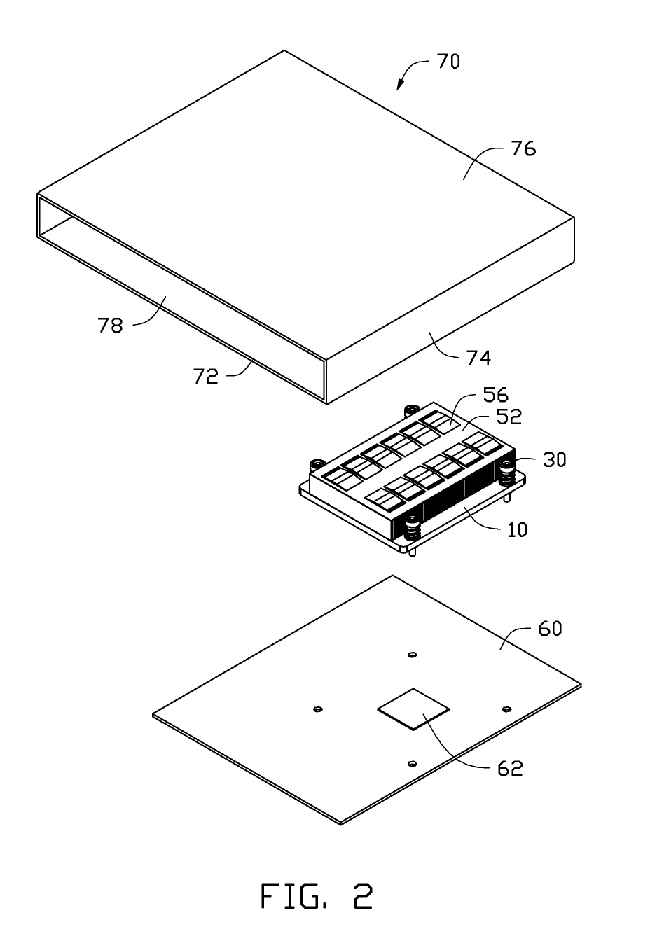

Referring to FIGS. 1 and 2, an electronic device in accordance with a first embodiment of the disclosure includes a metal housing 70, and a heat dissipation apparatus and a printed circuit board 60 both received in the metal housing 70. The heat dissipation apparatus is used for dissipating heat generated from an electronic component 62 on the printed circuit board 60, and includes a heat sink and a cover 50 covering the heat sink.

The metal housing 70 includes a bottom plate 72, two side plates 74 vertically and upwardly extending from two opposite outer edges of the bottom plate 72, and a top plate 76 interconnecting the two side plates 74. The bottom plate 72, the side plates 74 and the top plate 76 cooperatively form a chamber 78 for receiving the heat dissipation apparatus and the printed circuit board 60 therein. The printed circuit board 60 is located near the bottom plate 72 of the metal housing 70.

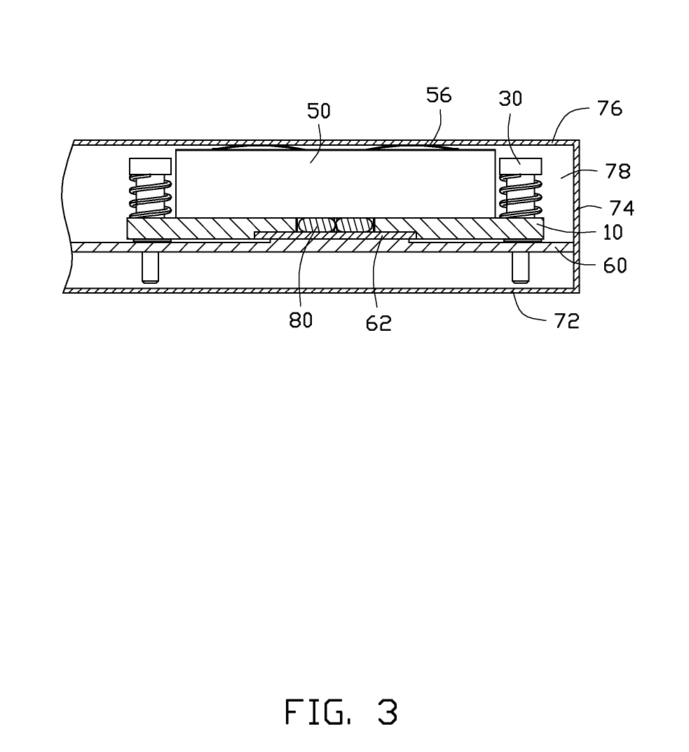

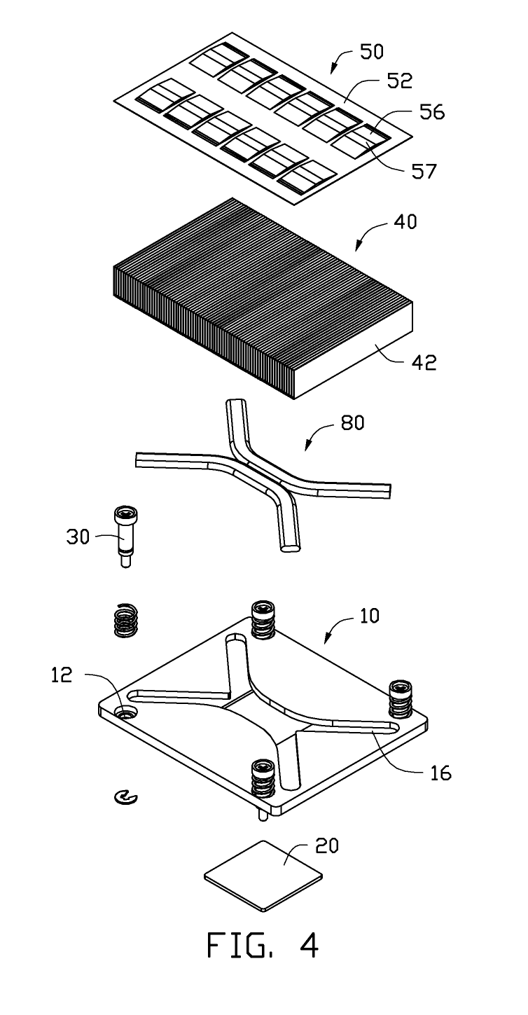

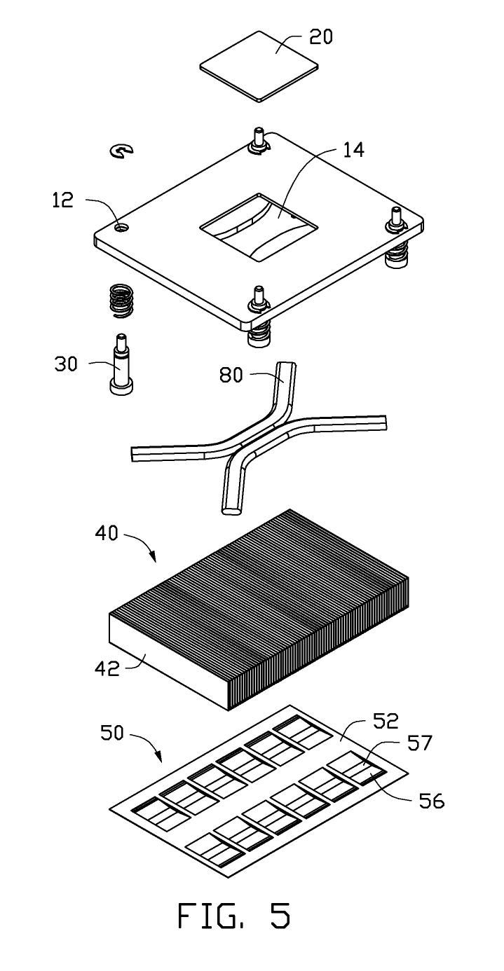

Also referring to FIGS. 3-5, the heat sink includes a heat conducting plate 10, a heat spreader 20 mounted at a bottom of the heat conducting plate 10, four fasteners 30 correspondingly attached to four corners of the heat conducting plate 10, and two heat pipes 80 and a fin assembly 40 both mounted at a top of the heat conducting plate 10.

The heat conducting plate 10 is made of metal such as aluminum, copper or an alloy thereof, and defines a rectangular opening 14 in a center of the bottom thereof. The heat spreader 20 is received in the opening 14. Four through holes 12 are correspondingly defined in the four corners of the heat conducting plate 10. The fasteners 30 extend through the through holes 12 of the heat conducting plate 10 and the printed circuit board 60 to mount the heat dissipation apparatus on the printed circuit board 60, and the heat spreader 20 is brought into intimate contact with the electronic component 62. An X-shaped receiving slot 16 is defined in a center of the top of the heat conducting plate 10 for receiving the heat pipes 80 therein. A center of the receiving slot 16 communicates with the opening 14 so that a top face of the heat spreader 20 can thermally contact bottom faces of the heat pipes 80.

The fin assembly 40 includes a plurality of fins 42 stacked together. The fins 42 each are made of metal such as aluminum, copper or an alloy thereof, and are spaced from each other.

The cover 50 is integrally made of a metal sheet and includes a rectangular body 52 and a plurality of strip-shaped resilient tabs 56. The body 52 of the cover 50 is soldered on the fins 42 of the fin assembly 40, so that a bottom face of the body 52 of the cover 50 thermally contacts top ends of the fins 42 of the fin assembly 40. The resilient tabs 56 are integrally formed by upwardly punching the body 52. Alternatively, the resilient tabs 56 can be fastened on the body 52 by soldering. The resilient tabs 56 are arranged in two symmetric rows. Two adjacent resilient tabs 56 in a same row are parallel to and spaced from each other. Two adjacent resilient tabs 56 respectively in different rows are in alignment with each other. Each resilient tab 56 protrudes upwardly relative to a top face of the body 52 and towards the metal housing 70, and has an arc-shaped profile. A horizontal contacting portion 57 is formed at a middle of each resilient tab 56. Each resilient tab 56 is elastically and slightly deformed by the top plate 76 of the metal housing 70, and the contacting portion 57 of each resilient tab 56 thermally contacts the top plate 76 of the metal housing 70. Since the contacting portion 57 is horizontal, a contacting area between the resilient tab 56 and the top plate 76 of the metal housing 70 is increased. Heat from the electronic component 62 can be transmitted to the heat spreader 20, fin assembly 40, resilient tabs 56 and the metal housing 70 in sequence, and be removed efficiently and timely via the relatively larger surface area of the metal housing 70.

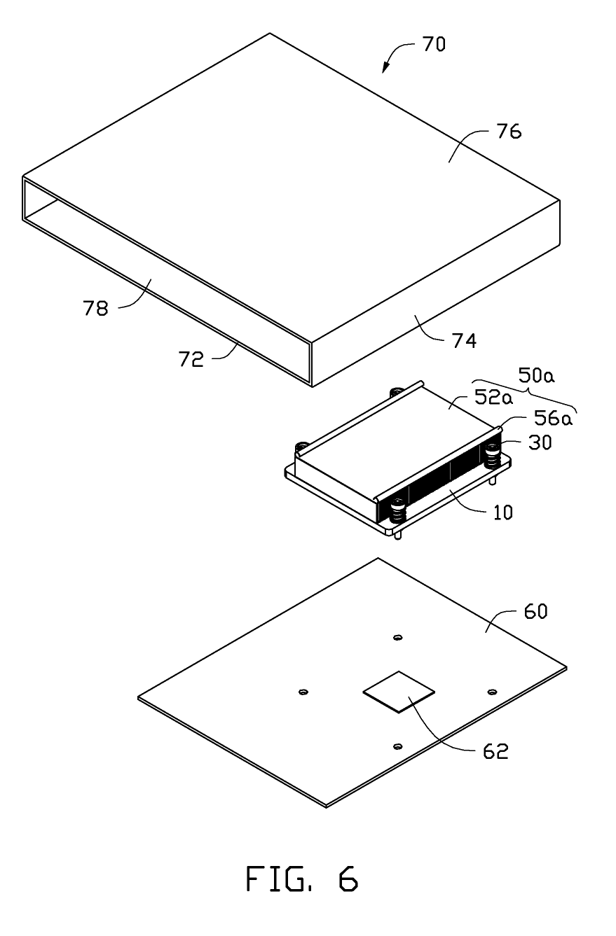

Referring to FIG. 6, an electronic device in accordance with a second embodiment of the disclosure includes a metal housing 70, a heat dissipation apparatus and a printed circuit board 60 both received in the metal housing 70. The heat dissipation apparatus includes a heat sink and a cover 50a covering the heat sink. The differences between the second embodiment and the first embodiment are in that: the cover 50a in the second embodiment includes a rectangular body 52a thermally contacting the heat sink and two raised resilient tabs 56a thermally and elastically contacting the metal housing 70; the resilient tabs 56a are formed by rolling over two opposite edges of the body 52a.

According to disclosure, the heat dissipation apparatus thermally contacting the metal housing 70 via the resilient tabs 56, 56a, heat from the electronic component 62 can be removed efficiently and timely via the relatively larger surface area of the metal housing 70.

It is believed that the disclosure and its advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A heat dissipation apparatus for cooling an electronic component received in a metal housing, comprising:
a heat sink for thermally connecting to the electronic component; and
a plurality of resilient tabs arranged between the heat sink and the metal housing, the resilient tabs being elastic for being elastically deformed by the metal housing and thermally contacting an inner face of the metal housing.

2. The heat dissipation apparatus of claim 1, further comprising a cover attached on the heat sink, the resilient tabs being formed on the cover.

3. The heat dissipation apparatus of claim 2, wherein the cover comprises a body, and the resilient tabs are integrally formed by punching the body.

4. The heat dissipation apparatus of claim 3, wherein the body of the cover is soldered on a top of the heat sink.

5. The heat dissipation apparatus of claim 2, wherein the cover comprises a body thermally contacting the heat sink, the resilient tabs being formed by rolling over two opposite edges of the body.

6. The heat dissipation apparatus of claim 3, wherein the heat sink comprises a plurality of fins stacked together, and a bottom face of the body of the cover thermally contacts top ends of the fins.

7. The heat dissipation apparatus of claim 3, wherein each of the resilient tabs protrudes upwardly relative to a top face of the body and towards the metal housing, and has a substantially arc-shaped profile.

8. The heat dissipation apparatus of claim 7, wherein a horizontal contacting portion is formed at a middle of each resilient tab for thermally contacting the metal housing.

9. The heat dissipation apparatus of claim 3, wherein the resilient tabs are arranged in two symmetric rows, two adjacent resilient tabs in a same row being parallel to and spaced from each other.

10. The heat dissipation apparatus of claim 9, wherein two adjacent resilient tabs respectively in different rows are in alignment with each other.

11. An electronic device, comprising:
a metal housing;
an electronic component received in the metal housing;
a heat sink thermally connected to the electronic component for removing heat from the electronic component; and
a plurality of resilient tabs arranged between the heat sink and the metal housing, the resilient tabs being elastically deformed by the metal housing and thermally contacting an inner face of the metal housing.

12. The electronic device of claim 11, further comprising a cover attached on the heat sink, the resilient tabs being formed on the cover.

13. The electronic device of claim 12, wherein the cover comprises a body, and the resilient tabs are integrally formed by punching the body.

14. The electronic device of claim 13, wherein the body of the cover is soldered on a top of the heat sink.

15. The electronic device of claim 12, wherein the cover comprises a body thermally contacting the heat sink, the resilient tabs being formed by rolling over two opposite edges of the body.

16. The electronic device of claim 13, wherein the heat sink comprises a plurality of fins stacked together, and a bottom face of the body of the cover thermally contacts top ends of the fins.

17. The electronic device of claim 13, wherein each of the resilient tabs protrudes upwardly relative to a top face of the body and towards the metal housing, and has a substantially arc-shaped profile.

18. The electronic device of claim 17, wherein a horizontal contacting portion is formed at a middle of each resilient tab and thermally contacts the metal housing.

19. The electronic device of claim 13, wherein the resilient tabs are arranged in two symmetric rows, two adjacent resilient tabs in a same row being parallel to and spaced from each other.

20. The electronic device of claim 19, wherein two adjacent resilient tabs respectively in different rows are in alignment with each other.
